(19) United States
(12) Patent Application Publication
(10) Pub. No.: US 2026/0242663 A1
(43) Pub. Date: Aug. 20, 2026

(54) ETCHANT COMPOSITION FOR ETCHING METAL NITRIDE LAYER AND METHOD OF FORMING PATTERN USING THE SAME

(71) Applicant: DONGWOO FINE-CHEM CO., LTD., Jeonbuk-do (KR)

(72) Inventors: GI WOO LEE, Jeonbuk-do (KR); JONG WOOK BAEK, Jeonbuk-do (KR); DONG GYU LEE, Jeonbuk-do (KR)

(21) Appl. No.: 19/544,167

(22) Filed: Feb. 19, 2026

(30) Foreign Application Priority Data
Feb. 20, 2025 (KR) 10-2025-0022090

(51) Int. Cl. C09K 13/08; H10D 64/01; H10P 50/26; H10P 50/66

(52) U.S. Cl. CPC C09K 13/08; H10D 64/01316; H10D 64/01354; H10P 50/269; H10P 50/667

(57) ABSTRACT

An etchant composition for etching a metal nitride layer includes an oxidizing agent, a fluorine-containing compound, an additive including a carbonate-based compound, and a remainder of water. In a method of forming a pattern, a metal pattern is formed on a substrate. A barrier layer including a metal nitride and covering the metal pattern is formed on the substrate. The barrier layer is etched using the etchant composition.

### CROSS-REFERENCE TO RELATED APPLICATION AND CLAIM OF PRIORITY

This application claims the benefit under 35 U.S.C. § 119 of Korean Patent Application No. 10-2025-0022090 filed on Feb. 20, 2025, in the Korean Intellectual Property Office, the entire disclosure of which is incorporated herein by reference for all purposes.

### BACKGROUND

### 1. Technical Field

The present invention relates to an etchant composition for etching a metal nitride layer and a method of forming a pattern using the same. More specifically, the present invention relates to an etchant composition for etching a metal nitride layer containing an oxidizing component and a method of forming a pattern using the same.

### 2. Description of the Related Art

For example, in a semiconductor device such as a DRAM, a NAND flash memory, a logic device, etc., or in a semiconductor device/wiring included in a display device, developments for achieving a high-speed operation while drastically reducing a critical dimension (CD) have been continued.

A low-resistance metal such as Co, W, Cu and Al can be used to form a conductive pattern such as a gate electrode, a contact and a wiring in the semiconductor device. A metal nitride layer can be temporarily formed as a protective layer or a barrier layer to protect the conductive pattern.

Accordingly, a selective etching process for the metal nitride layer may be included in the semiconductor device fabrication. However, if a semiconductor substrate, an insulating layer such as a silicon oxide layer, and the conductive pattern are damaged during the etching of the metal nitride layer, operational reliability of the semiconductor device may be reduced.

### SUMMARY

According to an aspect of the present invention, there is provided an etchant composition for etching a metal nitride layer providing enhanced etch stability and selectivity.

According to an aspect of the present invention, there is provided a method of forming a pattern using the etchant composition.

(1) An etchant composition for etching a metal nitride layer, including: an oxidizing agent; a fluorine-containing compound; an additive including a carbonate-based compound; and a remainder of water.

(2) The etchant composition of the above (1), wherein the oxidizing agent includes at least one selected from the group consisting of hydrogen peroxide, FeCl₃, Sr(NO₃)₂, oxone (2KHSO₅·HSO₄·K₂SO₄), periodic acid, iodic acid, vanadium oxide, ammonium vanadate, ammonium peroxymonosulfate, ammonium chlorite (NH₄ClO₂), ammonium chlorate (NH₄ClO₃), ammonium iodate (NH₄IO₃), ammonium nitrate (NH₄NO₃), ammonium perborate (NH₄BO₃), ammonium perchlorate (NH₄ClO₄), ammonium periodate (NH₄IO₄), ammonium persulfate ((NH₄)₂S₂O₈), ammonium hypochlorite (NH₄ClO), ammonium tungstate ((NH₄)₁₀H₂(W₂O₇)), sodium persulfate (Na₂S₂O₈), sodium hypochlorite (NaClO), sodium perborate, potassium iodate (KIO₃), potassium permanganate (KMnO₄), potassium persulfate, nitric acid (HNO₃), potassium persulfate (K₂S₂O₈), potassium hypochlorite (KClO), tetramethylammonium chlorite ((N(CH₃)₄)ClO₂), tetramethylammonium chlorate ((N(CH₃)₄)ClO₃), tetramethylammonium iodate ((N(CH₃)₄)IO₃), tetramethylammonium perborate ((N(CH₃)₄)BO₃), tetramethylammonium perchlorate ((N(CH₃)₄)ClO₄), tetramethylammonium periodate ((N(CH₃)₄)IO₄), tetramethylammonium persulfate ((N(CH₃)₄)S₂O₈), tetrabutylammonium peroxomonosulfate, peroxomonosulfuric acid, sulfuric acid, methanesulfonic acid, trifluoromethanesulfonic acid, benzenesulfonic acid, p-toluenesulfonic acid, 10-camphorsulfonic acid, ferric nitrate (Fe(NO₃)₃), urea hydrogen peroxide ((CO(NH₂)₂)H₂O₂), peracetic acid (CH₃(CO)OOH), 1,4-benzoquinone, toluquinone, dimethyl-1,4-benzoquinone, chloranil, alloxan, N-methylmorpholine N-oxide and trimethylamine N-oxide.

(3) The etchant composition of the above (1), wherein a content of the oxidizing agent is in a range from 0.0001 wt % to 10 wt % based on a total weight of the composition.

(4) The etchant composition of the above (1), wherein a content of the oxidizing agent is in a range from 0.001 wt % to 5 wt % based on a total weight of the composition.

(5) The etchant composition of the above (1), wherein the fluorine-containing compound includes at least one selected from the group consisting of H₂ZrF₆, hexafluorotitanic acid (H₂TiF₆), hydrofluoric acid, tetrafluoroboric acid, hexafluorophosphoric acid, hexafluorosilicic acid, ammonium hexafluorosilicate, ammonium hexafluorotitanate, ammonium fluoride, methylammonium fluoride, dimethylammonium fluoride, trimethylammonium fluoride, tetramethylammonium fluoride, tetraethylammonium fluoride, tetrapropylammonium fluoride, tetrabutylammonium fluoride and tetrapentylammonium fluoride.

(6) The etchant composition of the above (1), wherein a content of the fluorine-containing compound is in a range from 0.001 wt % to 10 wt % based on a total weight of the composition.

(7) The etchant composition of the above (1), wherein a content of the fluorine-containing compound is in a range from 0.01 wt % to 5 wt % based on the total weight of the composition.

(8) The etchant composition of the above (1), wherein the carbonate-based compound includes at least one selected from the group consisting of a carbonic acid, a carbonate salt, a bicarbonate salt and a methyl carbonate salt.

(9) The etchant composition of the above (8), wherein the carbonate salt, the bicarbonate salt and the methyl carbonate salt each includes a salt of at least one selected from the group consisting of ammonium, tetramethylammonium, tetraethylammonium, tetrapropylammonium, tetrabutylammonium, butyltrimethylammonium, tetrapentylammonium, hexyltrimethylammonium, heptyltrimethylammonium, octyltrimethylammonium, octylammonium, nonyltrimethylammonium, decyltrimethylammonium, undecyltrimethylammonium, dodecyltrimethylammonium, dodecylammonium, tridecyltrimethylammonium, tetradecyltrimethylammonium, pentadecyltrimethylammonium, hexadecyltrimethylammonium, heptadecyltrimethylammonium, octadecylammonium, octadecyltrimethylammonium and trimethylstearylammonium.

(10) The etchant composition of the above (1), wherein a content of the carbonate-based compound is in a range from 0.01 wt % to 20 wt % based on a total weight of the composition.

(11) The etchant composition of the above (1), wherein a content of the carbonate-based compound is in a range from 0.1 wt % to 10 wt % based on a total weight of the composition.

(12) A method of forming a pattern, including: forming a metal pattern on a substrate; forming a barrier layer including a metal nitride and covering the metal pattern on the substrate; and etching the barrier layer using the above-described etchant composition.

(13) The method of the above (12), further including heat-treating the barrier layer and the metal pattern before etching the barrier layer.

(14) The method of the above (12), wherein the metal pattern includes molybdenum (Mo) or tungsten (W), and the barrier layer includes titanium nitride (TiN).

According to embodiments of the present invention, an etchant composition of a metal nitride layer may include a metal protective agent including a carbonate-based compound. The metal protective agent may protect a metal layer or a metal pattern including molybdenum (Mo), tungsten (W), or the like, and may selectively etch the metal nitride layer.

In example embodiments, a barrier layer including titanium nitride (TiN) may be formed on a conductive pattern, and then an annealing process may be performed. Thereafter, the etchant composition may be used to selectively remove the barrier layer while suppressing etching damages to the conductive pattern.

Thus, the etchant composition may be used to form a conductive pattern such as a wiring, a gate electrodes, a contact, etc., of a semiconductor device with high reliability.

### BRIEF DESCRIPTION OF THE DRAWINGS

FIGS. 1 to 4 are schematic cross-sectional views illustrating a method of forming a pattern in accordance with example embodiments.

### DETAILED DESCRIPTION OF THE EMBODIMENTS

Embodiments of the present invention provide an etchant composition of a metal nitride layer including an oxidizing etching agent and a metal protective agent. Further, embodiments of the present invention provide a method of forming a pattern using the etchant composition.

The etchant composition of a metal nitride layer may be utilized in a selective etching process of a barrier layer including a metal nitride in a device process for forming a gate electrode, a wiring, etc., in a semiconductor device or an image display device.

In example embodiments, the etchant composition of a metal nitride layer may be used for a selective etching of a titanium nitride (TiN) layer.

Hereinafter, embodiments of the present invention will be described in detail. However, these embodiments are merely provided as examples, and the present disclosure is not limited to the specific embodiments described herein.

### <Etchant Composition for Metal Nitride Layer>

An etchant composition for a metal nitride layer (hereinafter, that may be abbreviated as “etchant composition”) according to example embodiments may include an oxidizing agent, a fluorine-containing compound and a carbonate-based compound, and may further include a remainder of water.

The oxidizing agent may be used as a main etching agent for a metal nitride, such as TiN. For example, the oxidizing agent may include a fluorine-free oxidizing compound.

For example, the oxidizing agent may include hydrogen peroxide, FeCl₃, Sr(NO₃)₂, oxone (2KHSO₅·HSO₄·K₂SO₄), periodic acid, iodic acid, vanadium oxide, ammonium vanadate, ammonium peroxymonosulfate, ammonium chlorite (NH₄ClO₂), ammonium chlorate (NH₄ClO₃), ammonium iodate (NH₄IO₃), ammonium nitrate (NH₄NO₃), ammonium perborate (NH₄BO₃), ammonium perchlorate (NH₄ClO₄), ammonium periodate (NH₄IO₄), ammonium persulfate ((NH₄)₂S₂O₈), ammonium hypochlorite (NH₄ClO), ammonium tungstate ((NH₄)₁₀H₂(W₂O₇)), sodium persulfate (Na₂S₂O₈), sodium hypochlorite (NaClO), sodium perborate, potassium iodate (KIO₃), potassium permanganate (KMnO₄), potassium persulfate, nitric acid (HNO₃), potassium persulfate (K₂S₂O₈), potassium hypochlorite (KClO), tetramethylammonium chlorite ((N(CH₃)₄)ClO₂), tetramethylammonium chlorate ((N(CH₃)₄)ClO₃), tetramethylammonium iodate ((N(CH₃)₄)IO₃), tetramethylammonium perborate ((N(CH₃)₄)BO₃), tetramethylammonium perchlorate ((N(CH₃)₄)ClO₄), tetramethylammonium periodate ((N(CH₃)₄)IO₄), tetramethylammonium persulfate ((N(CH₃)₄)S₂O₈), tetrabutylammonium peroxomonosulfate, peroxomonosulfuric acid, sulfuric acid, methanesulfonic acid, trifluoromethanesulfonic acid, benzenesulfonic acid, p-toluenesulfonic acid, 10-camphorsulfonic acid, ferric nitrate (Fe(NO₃)₃), urea hydrogen peroxide ((CO(NH₂)₂)H₂O₂), peracetic acid (CH₃(CO)OOH), 1,4-benzoquinone, toluquinone, dimethyl-1,4-benzoquinone, chloranil, alloxan, N-methylmorpholine N-oxide, trimethylamine N-oxide, etc. These may be used alone or in a combination of two or more therefrom.

In some embodiments, the oxidizing agent may include hydrogen peroxide, periodic acid, ammonium persulfate, hypochlorous acid, ammonium iodate, ammonium periodate, nitric acid, N-methylmorpholine N-oxide, sulfuric acid, methanesulfonic acid and/or benzenesulfonic acid. These may be used alone or in a combination of two or more therefrom.

In example embodiments, a content of the oxidizing agent may be in a range from 0.0001 wt % to 10 wt % based on a total weight of the etchant composition. In the above range, a sufficient etching rate of the metal nitride layer may be achieved while maintaining an appropriate oxidation rate.

In a preferable embodiment, the content of the oxidizing agent may be in a range from 0.001 wt % to 5 wt %. In this range, the etching rate of the TiN layer may be more effectively increased while suppressing an etching of a metal layer.

The fluorine-containing compound may be used as an etching agent for the metal nitride layer (e.g., the TiN layer) together with the oxidizing agent. The fluorine-containing compound may include hydrofluoric acid or a fluoride-based compound.

In example embodiments, the fluorine-containing compound may include H₂ZrF₆, hexafluorotitanic acid (H₂TiF₆), hydrofluoric acid, tetrafluoroboric acid, hexafluorophosphoric acid, hexafluorosilicic acid, ammonium hexafluorosilicate, ammonium hexafluorotitanate, ammonium fluoride, methylammonium fluoride, dimethylammonium fluoride, trimethylammonium fluoride, tetramethylammonium fluoride, tetraethylammonium fluoride, tetrapropylammonium fluoride, tetrabutylammonium fluoride, tetrapentylammonium fluoride, etc. may be included. These may be used alone or in combination of two or more therefrom.

In example embodiments, a content of the fluorine-containing compound may be in a range from 0.001 wt % to 10 wt % based on the total weight of the etchant composition. In this range, a sufficient etching rate of the metal nitride layer may be achieved while preventing damages to other layers such as SiO₂, SiN, and CoSi.

In a preferable embodiment, the content of the fluorine-containing compound may be in a range from 0.01 wt % to 5 wt %, more preferably from 0.01 wt % to 0.5 wt %. In the above range, the etching rate of the TiN layer may be more effectively increased while suppressing the etching of the metal layer.

In example embodiments, the etchant composition may include the carbonate-based compound as an additive. The carbonate-based compound may be included as a protective agent or anti-corrosion agent for a metal layer or a metal pattern including molybdenum (Mo), tungsten (W), or the like. The carbonate-based compound may suppress etching of the metal layer while improving an etch selectivity of a metal nitride layer such as the TiN layer.

The carbonate-based compound may include a carbonic acid, a carbonate salt, a bicarbonate (carbonate hydrogen) salt, and/or a methyl carbonate salt.

In example embodiments, the carbonate salt, the bicarbonate salt and the methyl carbonate salt may include a carbonate salt, a bicarbonate salt and a methyl carbonate salt of ammonium, tetramethylammonium, tetraethylammonium, tetrapropylammonium, tetrabutylammonium, butyltrimethylammonium, tetrapentylammonium, hexyltrimethylammonium, heptyltrimethylammonium, octyltrimethylammonium, octylammonium, nonyltrimethylammonium, decyltrimethylammonium, undecyltrimethylammonium, dodecyltrimethylammonium, dodecylammonium, tridecyltrimethylammonium, tetradecyltrimethylammonium, pentadecyltrimethylammonium, hexadecyltrimethylammonium, heptadecyltrimethylammonium, octadecylammonium, octadecyltrimethylammonium, trimethylstearylammonium, or the like.

In example embodiments, the content of the carbonate-based compound based on the total weight of the etchant composition may be in a range from 0.01 wt % to 20 wt %. In the above range, etching of the metal layer may be sufficiently suppressed while improving etching uniformity of the metal nitride layer. For example, if the content of the carbonate-based compound increases excessively, etching uniformity may be deteriorated due to adsorption with the metal nitride layer.

Preferably, the content of the carbonate-based compound may be in a range from 0.1 wt % to 10 wt %, more preferably from 0.1 wt % to 5 wt %.

The etchant composition may include a remainder or balance of water. For example, deionized water used in a semiconductor processing may be used.

As used herein, the terms “remainder” or “balance” are used in a variable/open sense indicating a remaining amount after excluding the aforementioned components, or a remaining amount after further excluding additional components.

The etchant composition may further include an additive within a range that does not hinder effects of the oxidizing agent, the fluorine-containing compound and the carbonate-based compound as described above.

For example, the etchant composition may further include a pH adjusting agent, a surfactant, an auxiliary oxidizing agent, or the like, that may be widely used in the etchant field.

The pH adjusting agent may include an acidic compound or an alkaline compound. Examples of the acidic compound include an inorganic acid such as nitric acid or a salt thereof, or an organic acid such as acetic acid, lactic acid, oxalic acid, tartaric acid, citric acid, etc., or a salt thereof. Examples of the alkaline compound include ammonia or an ammonium-based compound.

Examples of the surfactant include a cationic surfactant, an anionic surfactant, or an amphoteric surfactant.

Examples of the auxiliary oxidizing agent include a peroxide, an inorganic acid salt, a persulfuric acid, a persulfate, or the like.

In some embodiments, the etchant composition may not include a chelating agent compound such as ethylenediamine tetraacetic acid (EDTA), EDTA-2NH₃ (ethylenediamine tetraacetic acid diammonium salt), (1,2-cyclohexylenedinitrilo)tetraacetic acid (CDTA), diethylenetriamine pentaacetic acid (DTPA), 2-phosphonobutane-1,2,4-tricarboxylic acid (PBTCA), etc. In some embodiments, the etchant composition may not include an organic solvent, such as an alcohol-based solvent, other than water. For example, the chelating agent and the organic solvent may interact with each other to reduce an etching rate of the TiN layer.

In some embodiments, the etchant composition may provide an etching rate of about 40 Å/min or more, preferably about 50 Å/min or more, more preferably about 60 Å/min, for the TiN layer at 60° C. and 400 rpm.

In some embodiments, the etchant composition may provide an etch selectivity of 20 or greater, preferably 30 or greater, and more preferably 40 or greater for the TiN layer relative to a Mo layer or a W layer at 60° C. and 400 rpm.

### <Method of Forming Pattern>

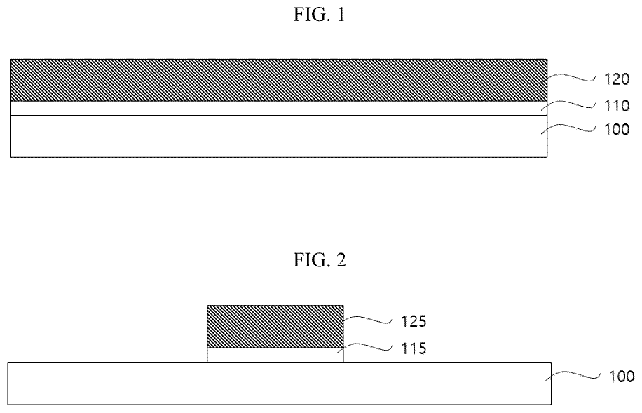

FIGS. 1 to 4 are schematic cross-sectional views illustrating a method of forming a pattern according to embodiments.

Referring to FIG. 1, an insulating layer 110 and a metal layer 120 may be formed on a substrate 100.

The substrate 100 may include a semiconductor material such as single-crystalline silicon or single-crystalline germanium, and may also be formed to include polysilicon.

The insulating layer 110 may be formed to include an insulating material such as silicon oxide, silicon nitride, silicon oxynitride, polysiloxane, or the like. For example, the insulating layer 110 may be formed by a chemical vapor deposition (CVD) process, a sputtering process, a physical vapor deposition (PVD) process, an atomic layer deposition (ALD) process, or the like.

The metal layer 120 may be formed on the insulating layer 110. In example embodiments, the metal layer 120 may be formed by a sputtering process or a PVD process to include a metal such as molybdenum (Mo) or tungsten (W).

Referring to FIG. 2, the metal layer 120 and the insulating layer 110 may be etched to form a metal pattern 125 and an insulating pattern 115. The metal layer 120 and the insulating layer 110 may be etched together by a dry etching, or sequentially etched by a wet etching using different etchant solutions.

In example embodiments, the insulating pattern 115 may serve as a gate insulating pattern of a semiconductor device, and the metal pattern 125 may serve as a gate electrode of the semiconductor device.

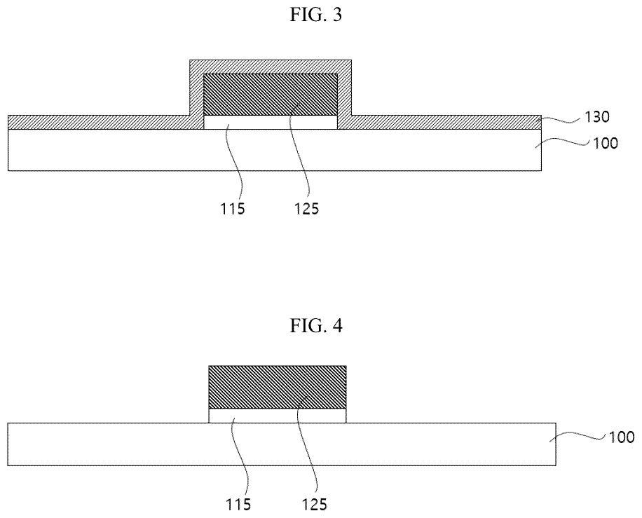

Referring to FIG. 3, a barrier layer 130 covering the metal pattern 125 and the insulating pattern 115 may be formed on the substrate 100. The barrier layer 130 may be formed by a sputtering process or a PVD process to include a metal nitride such as TiN.

Thereafter, a heat treatment process or an annealing process may be performed to stabilize a crystal structure of the metal pattern 125. During the heat treatment process or the annealing process, the barrier layer 130 may block diffusion of metal components.

Referring to FIG. 4, the barrier layer 130 may be etched using the etchant composition according to the above-described embodiments of the present disclosure. Accordingly, the barrier layer 130 may be substantially removed. For example, the barrier layer 130 may be removed by spraying and/or immersing the above-described etchant composition.

As described above, the barrier layer 130 may be etched by the interaction of the oxidizing agent and the fluorine-containing compound, and the carbonate-based compound may act as a metal protector or an anti-corrosion agent, thereby suppressing etching damages to the metal pattern 125. Additionally, the carbonate-based compound may also suppress etching damages to the insulating pattern 115 and the substrate 100. Further, uniform etching of the barrier layer 130 may be implemented to prevent a metal nitride residue.

Hereinafter, embodiments of the present disclosure will be further described with reference to specific experimental examples. Examples and comparative examples included in the experimental examples are merely provided to facilitate understanding of the present disclosure and are not intended to limit the scope of the appended claims, and it is obvious to those skilled in the art that various changes and modifications to the examples are possible within the scope and technical spirit of the present disclosure, and it is also obvious that such variations and modifications fall within the scope of the appended claims.

### Examples and Comparative Examples

The compounds described in Table 3 below were mixed in corresponding amounts (wt) as shown in Table 1 (Examples) and Table 2 (Comparative Examples), and a remainder of water was commonly included to prepare etchant compositions for Examples and Comparative Examples.

TABLE 1

| | oxidizing | | fluorine-containing | | | | |
|---|---|---|---|---|---|---|---|
| | agent | | compound | | additive | | |
| | | content | | content | | content | |
| | compound | (wt %) | compound | (wt %) | compound | (wt %) | water |
| Example 1 | A-1 | 0.0005 | B-1 | 0.5 | C-1 | 5 | remainder |
| Example 2 | A-1 | 0.0001 | B-1 | 0.5 | C-1 | 5 | remainder |
| Example 3 | A-1 | 0.001 | B-1 | 0.5 | C-1 | 5 | remainder |
| Example 4 | A-1 | 5 | B-1 | 0.5 | C-1 | 5 | remainder |
| Example 5 | A-1 | 7 | B-1 | 0.5 | C-1 | 5 | remainder |
| Example 6 | A-1 | 10 | B-1 | 0.5 | C-1 | 5 | remainder |
| Example 7 | A-1 | 15 | B-1 | 0.5 | C-1 | 5 | remainder |
| Example 8 | A-1 | 0.1 | B-1 | 0.0005 | C-1 | 5 | remainder |
| Example 9 | A-1 | 0.1 | B-1 | 0.001 | C-1 | 5 | remainder |
| Example 10 | A-1 | 0.1 | B-1 | 0.01 | C-1 | 5 | remainder |
| Example 11 | A-1 | 0.1 | B-1 | 0.5 | C-1 | 5 | remainder |
| Example 12 | A-1 | 0.1 | B-1 | 0.7 | C-1 | 5 | remainder |
| Example 13 | A-1 | 0.1 | B-1 | 10 | C-1 | 5 | remainder |
| Example 14 | A-1 | 0.1 | B-1 | 15 | C-1 | 5 | remainder |
| Example 15 | A-1 | 0.1 | B-1 | 0.5 | C-1 | 0.005 | remainder |
| Example 16 | A-1 | 0.1 | B-1 | 0.5 | C-1 | 0.01 | remainder |
| Example 17 | A-1 | 0.1 | B-1 | 0.5 | C-1 | 0.1 | remainder |
| Example 18 | A-1 | 0.1 | B-1 | 0.5 | C-1 | 10 | remainder |
| Example 19 | A-1 | 0.1 | B-1 | 0.5 | C-1 | 12 | remainder |
| Example 20 | A-1 | 0.1 | B-1 | 0.5 | C-1 | 20 | remainder |
| Example 21 | A-1 | 0.1 | B-1 | 0.5 | C-1 | 25 | remainder |
| Example 22 | A-2 | 0.0005 | B-2 | 0.5 | C-2 | 5 | remainder |
| Example 23 | A-2 | 0.0001 | B-2 | 0.5 | C-2 | 5 | remainder |
| Example 24 | A-2 | 0.001 | B-2 | 0.5 | C-2 | 5 | remainder |
| Example 25 | A-2 | 5 | B-2 | 0.5 | C-2 | 5 | remainder |
| Example 26 | A-2 | 10 | B-2 | 0.5 | C-2 | 5 | remainder |
| Example 27 | A-2 | 15 | B-2 | 0.5 | C-2 | 5 | remainder |
| Example 28 | A-2 | 0.1 | B-2 | 0.0005 | C-2 | 5 | remainder |
| Example 29 | A-2 | 0.1 | B-2 | 0.001 | C-2 | 5 | remainder |
| Example 30 | A-2 | 0.1 | B-2 | 0.01 | C-2 | 5 | remainder |
| Example 31 | A-2 | 0.1 | B-2 | 0.5 | C-2 | 5 | remainder |
| Example 32 | A-2 | 0.1 | B-2 | 10 | C-2 | 5 | remainder |
| Example 33 | A-2 | 0.1 | B-2 | 15 | C-2 | 5 | remainder |
| Example 34 | A-2 | 0.1 | B-2 | 0.5 | C-2 | 0.005 | remainder |
| Example 35 | A-2 | 0.1 | B-2 | 0.5 | C-2 | 0.01 | remainder |
| Example 36 | A-2 | 0.1 | B-2 | 0.5 | C-2 | 0.1 | remainder |
| Example 37 | A-2 | 0.1 | B-2 | 0.5 | C-2 | 10 | remainder |
| Example 38 | A-2 | 0.1 | B-2 | 0.5 | C-2 | 20 | remainder |
| Example 39 | A-2 | 0.1 | B-2 | 0.5 | C-2 | 25 | remainder |
| Example 40 | A-3 | 0.1 | B-3 | 0.5 | C-3 | 5 | remainder |
| Example 41 | A-4 | 0.1 | B-4 | 0.5 | C-4 | 5 | remainder |
| Example 42 | A-5 | 0.1 | B-5 | 0.5 | C-5 | 5 | remainder |
| Example 43 | A-6 | 1.0 | B-6 | 0.5 | C-6 | 5 | remainder |
| Example 44 | A-7 | 1.0 | B-7 | 0.5 | C-7 | 5 | remainder |
| Example 45 | A-8 | 1.0 | B-8 | 0.5 | C-8 | 5 | remainder |
| Example 46 | A-9 | 1.0 | B-9 | 0.5 | C-9 | 5 | remainder |
| Example 47 | A-1 | 0.1 | B-1 | 0.5 | C-1 | 5 | remainder |
| | A-9 | 1.0 | | | | | |
| Example 48 | A-2 | 0.1 | B-2 | 0.5 | C-2 | 5 | remainder |
| | A-10 | 1.0 | | | | | |
| Example 49 | A-3 | 0.1 | B-3 | 0.5 | C-3 | 5 | remainder |
| | A-11 | 1.0 | | | | | |
| Example 50 | A-9 | 0.1 | B-9 | 0.5 | C-1 | 2.5 | remainder |
| | | | | | C-12 | 2.5 | |

TABLE 2

| | oxidizing | | fluorine-containing | | | | |
|---|---|---|---|---|---|---|---|
| | agent | | compound | | additive | | |
| | | content | | content | | content | |
| | compound | (wt %) | compound | (wt %) | compound | (wt %) | water |
| Comparative | — | — | B-1 | 0.5 | C-1 | 5 | remainder |
| Example 1 | | | | | | | |
| Comparative | A-1 | 0.1 | — | — | C-1 | 5 | remainder |
| Example 2 | | | | | | | |
| Comparative | A-1 | 0.1 | B-1 | 0.5 | — | — | remainder |
| Example 3 | | | | | | | |
| Comparative | — | — | B-2 | 0.5 | C-2 | 5 | remainder |
| Example 4 | | | | | | | |
| Comparative | A-2 | 0.1 | — | — | C-2 | 5 | remainder |
| Example 5 | | | | | | | |
| Comparative | A-2 | 0.1 | B-2 | 0.5 | — | — | remainder |
| Example 6 | | | | | | | |
| Comparative | A-1 | 0.1 | B-1 | 0.5 | C-10 | 5 | remainder |
| Example 7 | | | | | | | |
| Comparative | A-2 | 0.1 | B-2 | 0.5 | C-11 | 5 | remainder |
| Example 8 | | | | | | | |

TABLE 3

| No. | compound |
|---|---|
| A-1 | hydrogen peroxide |
| A-2 | periodic acid |
| A-3 | ammonium persulfate |
| A-4 | hypochlorous acid |
| A-5 | ammonium iodate |
| A-6 | nitric acid |
| A-7 | N-methylmorpholine N-oxide |
| A-8 | ammonium periodate |
| A-9 | sulfuric acid |
| A-10 | methanesulfonic acid |
| A-11 | benzenesulfonic acid |
| B-1 | tetramethylammonium fluoride |
| B-2 | tetraethylammonium fluoride |
| B-3 | tetrapropylammonium fluoride |
| B-4 | tetrabutylammonium fluoride |
| B-5 | fluorosilicic acid |
| B-6 | hexafluorotitanic acid |
| B-7 | hexafluorophosphoric acid |
| B-8 | hydrofluoric acid |
| B-9 | ammonium fluoride |
| C-1 | hexadecylammonium bicarbonate |
| C-2 | dodecyltrimethylammonium carbonate |
| C-3 | tetradecyltrimethylammonium bicarbonate |
| C-4 | ammonium bicarbonate |
| C-5 | octyltrimethylammonium bicarbonate |
| C-6 | nonyltrimethylammonium bicarbonate |
| C-7 | octylammonium bicarbonate |
| C-8 | carbonic acid |
| C-9 | decyltrimethylammonium bicarbonate |
| C-10 | ammonium hydroxide |
| C-11 | hexadecylammonium bromide |
| C-12 | chelating agent(EDTA) |

### Experimental Example

### (1) Evaluation on Etching Properties for TiN, SiO₂, SiN, CoSi, Mo and W

Wafers each including layers of TiN, SiO₂, SiN, CoSi, Mo and W with a thickness of 2,000 Å were cut into a size of 1.5 cm×1.5 cm to prepare samples. The samples were immersed in each etchant composition of Examples and Comparative Examples at 60° C. and 400 rpm. The samples containing TiN, W and Mo layers were immersed for 1 minute, while the samples containing SiO₂, SiN and CoSi layers were immersed for 5,000 seconds.

Each sample was taken out, rinsed with water, and dried. Thereafter, a thickness of each layer was measured using an XRF or an ellipsometer. Etch rates of the TiN, Mo and W layers were calculated using a changes in a layer thickness.

The etch rate of the TiN layer was evaluated according to Table 4 below. A selectivity (Ti/metal) was calculated as a ratio of the etch rate of the TiN layer to the etch rates of the Mo and W layers, and was evaluated as shown in Table 5 below.

TABLE 4
Evaluation on TiN etch rate

| level | Å/min |
|---|---|
| 1 | less than 5 |
| 2 | 5 or more, less than 10 |
| 3 | 10 or more, less than 20 |
| 4 | 20 or more, less than 40 |
| 5 | 40 or more, less than 60 |
| 6 | 60 or more |

TABLE 5
TiN/metal(Mo, W) selectivity

| level | selectivity |
|---|---|
| 1 | less than 5 |
| 2 | 5 or more, less than 20 |
| 3 | 20 or more |

The etch rates of the samples including SiO₂, SiN and CoSi layers were measured to evaluate etch damages as shown in Table 6 below.

TABLE 6
SiO₂, SiN, CoSi damages

| level | Å/min |
|---|---|
| 1 | 10 or more |
| 2 | 2 or more, less than 10 |
| 3 | less than 2 |

### (2) Evaluation on TiN Surface Property

Wafers on which Mo and W layers were each deposited to a thickness of 2,000 Å were cut into a size of 1.5 cm×1.5 cm to prepare samples. The samples were immersed in the etchant compositions of Examples and Comparative Examples at 60° C. and 400 rpm for 1 minute. The samples were taken out, rinsed with water, and then air-dried. Thereafter, a surface roughness was measured using an AFM and evaluated as shown in Table 7 below.

TABLE 7
TiN surface property

| RMS(nm) | level |
|---|---|
| less than 2 | ⊚ |
| 2 or more, less than 3 | Δ |
| 3 or more | X |

The evaluation results are shown in Tables 8 and 9 below.

TABLE 8

| | | | SiO₂, SiN, | |
|---|---|---|---|---|
| | | TiN/metal | CoSi | TiN |
| | TiN etch rate | selectivity | damages | surface |
| | (Level) | (Level) | (Level) | property |
| Example 1 | 4 | 1 | 3 | ⊚ |
| Example 2 | 5 | 2 | 3 | ⊚ |
| Example 3 | 6 | 3 | 3 | ⊚ |
| Example 4 | 6 | 3 | 3 | ⊚ |
| Example 5 | 5 | 3 | 3 | ⊚ |
| Example 6 | 5 | 3 | 3 | ⊚ |
| Example 7 | 5 | 2 | 3 | ⊚ |
| Example 8 | 3 | 3 | 3 | ⊚ |
| Example 9 | 5 | 3 | 3 | ⊚ |
| Example 10 | 6 | 3 | 3 | ⊚ |
| Example 11 | 6 | 3 | 3 | ⊚ |
| Example 12 | 6 | 3 | 2 | ⊚ |
| Example 13 | 6 | 3 | 2 | ⊚ |
| Example 14 | 6 | 3 | 1 | ⊚ |
| Example 15 | 6 | 1 | 3 | ⊚ |
| Example 16 | 6 | 2 | 3 | ⊚ |
| Example 17 | 6 | 3 | 3 | ⊚ |
| Example 18 | 6 | 3 | 3 | ⊚ |
| Example 19 | 6 | 3 | 3 | Δ |
| Example 20 | 6 | 3 | 3 | Δ |
| Example 21 | 6 | 3 | 3 | X |
| Example 22 | 4 | 1 | 3 | ⊚ |
| Example 23 | 5 | 2 | 3 | ⊚ |
| Example 24 | 6 | 3 | 3 | ⊚ |
| Example 25 | 6 | 3 | 3 | ⊚ |
| Example 26 | 5 | 3 | 3 | ⊚ |
| Example 27 | 5 | 2 | 3 | ⊚ |
| Example 28 | 3 | 3 | 3 | ⊚ |
| Example 29 | 5 | 3 | 3 | ⊚ |
| Example 30 | 6 | 3 | 3 | ⊚ |
| Example 31 | 6 | 3 | 3 | ⊚ |
| Example 32 | 6 | 3 | 2 | ⊚ |
| Example 33 | 6 | 3 | 1 | ⊚ |
| Example 34 | 6 | 1 | 3 | ⊚ |
| Example 35 | 6 | 2 | 3 | ⊚ |
| Example 36 | 6 | 3 | 3 | ⊚ |
| Example 37 | 6 | 3 | 3 | ⊚ |
| Example 38 | 6 | 3 | 3 | Δ |
| Example 39 | 6 | 3 | 3 | X |
| Example 40 | 6 | 3 | 3 | ⊚ |
| Example 41 | 6 | 3 | 3 | ⊚ |
| Example 42 | 6 | 3 | 3 | ⊚ |
| Example 43 | 6 | 3 | 3 | ⊚ |
| Example 44 | 6 | 3 | 3 | ⊚ |
| Example 45 | 6 | 3 | 3 | ⊚ |
| Example 46 | 6 | 3 | 3 | ⊚ |
| Example 47 | 6 | 3 | 3 | ⊚ |
| Example 48 | 6 | 3 | 3 | ⊚ |
| Example 49 | 6 | 3 | 3 | ⊚ |
| Example 50 | 5 | 3 | 3 | Δ |

TABLE 9

| | | | SiO₂, SiN, | |
|---|---|---|---|---|
| | | TiN/metal | CoSi | TiN |
| | TiN etch rate | selectivity | damages | surface |
| | (Level) | (Level) | (Level) | property |
| Comparative | 1 | 1 | 3 | ⊚ |
| Example 1 | | | | |
| Comparative | 1 | 1 | 3 | ⊚ |
| Example 2 | | | | |
| Comparative | 6 | 1 | 3 | ⊚ |
| Example 3 | | | | |
| Comparative | 1 | 1 | 3 | ⊚ |
| Example 4 | | | | |
| Comparative | 1 | 1 | 3 | ⊚ |
| Example 5 | | | | |
| Comparative | 6 | 1 | 3 | ⊚ |
| Example 6 | | | | |
| Comparative | 6 | 1 | 3 | ⊚ |
| Example 7 | | | | |
| Comparative | 6 | 1 | 3 | ⊚ |
| Example 8 | | | | |

Referring to Tables 8 and 9, in Examples using the oxidizing agent, the fluorine-containing compound and the carbonate-based compound, sufficient etch rates for the TiN layer were achieved while suppressing etch damages to the metal layer and other inorganic layers.

In Comparative Examples 1, 2, 4 and 5, the carbonate-based compound was included, but the oxidizing agent or the fluorine-containing compound was omitted to result in reduction of the TiN etch rate and etch selectivity.

In Comparative Examples 3 and 6, the carbonate-based compound was omitted to increase the etch damages to the metal layer and other inorganic layers and result in reduction of the etch selectivity.

In Comparative Examples 7 and 8, where ammonium salts were used instead of the carbonate salt, the etch damages to the metal layer and other inorganic layers were significantly increased.

In Example 50 where a chelating agent was used together with the carbonate-based compound, the TiN layer etch rate and etch uniformity were relatively reduced.

What is claimed is:

1. An etchant composition for etching a metal nitride layer, comprising:
an oxidizing agent;
a fluorine-containing compound;
an additive comprising a carbonate-based compound; and
a remainder of water.

2. The etchant composition of claim 1, wherein the oxidizing agent includes at least one selected from the group consisting of hydrogen peroxide, FeCl₃, Sr(NO₃)₂, oxone (2KHSO₅·HSO₄·K₂SO₄), periodic acid, iodic acid, vanadium oxide, ammonium vanadate, ammonium peroxymonosulfate, ammonium chlorite (NH₄ClO₂), ammonium chlorate (NH₄ClO₃), ammonium iodate (NH₄IO₃), ammonium nitrate (NH₄NO₃), ammonium perborate (NH₄BO₃), ammonium perchlorate (NH₄ClO₄), ammonium periodate (NH₄IO₄), ammonium persulfate ((NH₄)₂S₂O₈), ammonium hypochlorite (NH₄ClO), ammonium tungstate ((NH₄)₁₀H₂(W₂O₇)), sodium persulfate (Na₂S₂O₈), sodium hypochlorite (NaClO), sodium perborate, potassium iodate (KIO₃), potassium permanganate (KMnO₄), potassium persulfate, nitric acid (HNO₃), potassium persulfate (K₂S₂O₈), potassium hypochlorite (KClO), tetramethylammonium chlorite ((N(CH₃)₄)ClO₂), tetramethylammonium chlorate ((N(CH₃)₄)ClO₃), tetramethylammonium iodate ((N(CH₃)₄)IO₃), tetramethylammonium perborate ((N(CH₃)₄)BO₃), tetramethylammonium perchlorate ((N(CH₃)₄)ClO₄), tetramethylammonium periodate ((N(CH₃)₄)IO₄), tetramethylammonium persulfate ((N(CH₃)₄)S₂O₈), tetrabutylammonium peroxomonosulfate, peroxomonosulfuric acid, sulfuric acid, methanesulfonic acid, trifluoromethanesulfonic acid, benzenesulfonic acid, p-toluenesulfonic acid, 10-camphorsulfonic acid, ferric nitrate (Fe(NO₃)₃), urea hydrogen peroxide ((CO(NH₂)₂)H₂O₂), peracetic acid (CH₃(CO)OOH), 1,4-benzoquinone, toluquinone, dimethyl-1,4-benzoquinone, chloranil, alloxan, N-methylmorpholine N-oxide and trimethylamine N-oxide.

3. The etchant composition of claim 1, wherein a content of the oxidizing agent is in a range from 0.0001 wt % to 10 wt % based on a total weight of the composition.

4. The etchant composition of claim 1, wherein a content of the oxidizing agent is in a range from 0.001 wt % to 5 wt % based on a total weight of the composition.

5. The etchant composition of claim 1, wherein the fluorine-containing compound includes at least one selected from the group consisting of H₂ZrF₆, hexafluorotitanic acid (H₂TiF₆), hydrofluoric acid, tetrafluoroboric acid, hexafluorophosphoric acid, hexafluorosilicic acid, ammonium hexafluorosilicate, ammonium hexafluorotitanate, ammonium fluoride, methylammonium fluoride, dimethylammonium fluoride, trimethylammonium fluoride, tetramethylammonium fluoride, tetraethylammonium fluoride, tetrapropylammonium fluoride, tetrabutylammonium fluoride and tetrapentylammonium fluoride.

6. The etchant composition of claim 1, wherein a content of the fluorine-containing compound is in a range from 0.001 wt % to 10 wt % based on a total weight of the composition.

7. The etchant composition of claim 1, wherein a content of the fluorine-containing compound is in a range from 0.01 wt % to 5 wt % based on the total weight of the composition.

8. The etchant composition of claim 1, wherein the carbonate-based compound includes at least one selected from the group consisting of a carbonic acid, a carbonate salt, a bicarbonate salt and a methyl carbonate salt.

9. The etchant composition of claim 8, wherein the carbonate salt, the bicarbonate salt and the methyl carbonate salt each includes a salt of at least one selected from the group consisting of ammonium, tetramethylammonium, tetraethylammonium, tetrapropylammonium, tetrabutylammonium, butyltrimethylammonium, tetrapentylammonium, hexyltrimethylammonium, heptyltrimethylammonium, octyltrimethylammonium, octylammonium, nonyltrimethylammonium, decyltrimethylammonium, undecyltrimethylammonium, dodecyltrimethylammonium, dodecylammonium, tridecyltrimethylammonium, tetradecyltrimethylammonium, pentadecyltrimethylammonium, hexadecyltrimethylammonium, heptadecyltrimethylammonium, octadecylammonium, octadecyltrimethylammonium and trimethylstearylammonium.

10. The etchant composition of claim 1, wherein a content of the carbonate-based compound is in a range from 0.01 wt % to 20 wt % based on a total weight of the composition.

11. The etchant composition of claim 1, wherein a content of the carbonate-based compound is in a range from 0.1 wt % to 10 wt % based on a total weight of the composition.

12. A method of forming a pattern, the method comprising:
forming a metal pattern on a substrate;
forming a barrier layer including a metal nitride and covering the metal pattern on the substrate; and
etching the barrier layer using the etchant composition of claim 1.

13. The method of claim 12, further comprising heat-treating the barrier layer and the metal pattern before etching the barrier layer.

14. The method of claim 12, wherein the metal pattern includes molybdenum (Mo) or tungsten (W), and the barrier layer includes titanium nitride (TiN).
